(19) United States
(12) Patent Application Publication
(10) Pub. No.: US 2013/0264444 A1
(43) Pub. Date: Oct. 10, 2013

(54) HARD DISK BRACKET

(71) Applicant: Shang-Hao Su, Taipei (TW)

(72) Inventor: Shang-Hao Su, Taipei (TW)

(73) Assignee: PRIMAX ELECTRONICS LTD., Taipei (TW)

(21) Appl. No.: 13/555,617

(22) Filed: Jul. 23, 2012

(30) Foreign Application Priority Data
Apr. 6, 2012 (TW) 101112211

(51) Int. Cl. H05K 7/14

(52) U.S. Cl. 248/221.11

(57) ABSTRACT

A hard disc bracket is provided for fixing a hard disc within a computer case. The hard disc bracket includes a frame, at least one pushing lever, and a pulling lever. The at least one pushing lever is located at a side of the frame and rotatable relative the frame. The pulling lever is disposed on the frame and movable relative to the frame. When the frame is stored within the computer case and the pulling lever is pulled out, the at least one pushing lever is moved by the pulling lever and rotated relative to the frame, so that the computer case is pushed by the at least one pushing lever and the frame is detached from the computer case.

### FIELD OF THE INVENTION

The present invention relates to a bracket, and more particularly to a hard disc bracket for fixing a hard disc within a computer case.

### BACKGROUND OF THE INVENTION

With rapid development of electronic and information industries, computers and the peripheral device thereof become essential parts in our daily lives. In addition to the working purposes, computers can be employed as amusement tools. Generally, a computer comprises a display screen, a computer case, a motherboard, a hard disc, a microprocessor, a memory, and other components. Recently, the manufacturers of the computers pay much attention to these components and try to improve the outward appearance, performance and use lives of these components. In these components of the computer, the microprocessor and the memory are mounted on the motherboard, and the hard disc is fixed on the computer case.

Conventionally, the hard disc is directly fixed on the computer case by screwing means. For facilitating the user to remove the hard disc, the hard disc may be firstly supported on a hard disc bracket, and then the hard disc bracket is stored within the computer case. In addition, the hard disc bracket is detachably connected to the computer case. By means of the hard disc bracket, the hard disc can be removed from the computer case or stored within the computer case more easily.

Hereinafter, the structure of a conventional hard disc bracket will be illustrated with reference to FIG. 1. FIG. 1 is a schematic perspective view illustrating the relationship between a hard disc bracket and a computer case according to the prior art. In FIG. 1, a hard disc bracket 1 and a computer case 2 are shown. The hard disc bracket 1 is used for accommodating a hard disc (not shown). In addition, the hard disc bracket 1 may be stored within the computer case 2. The computer case 2 comprises two sliding tracks 20 and two openings 21. The two sliding tracks 20 are located at two sides of the computer case 2. Since the two side plates 10 of the hard disc bracket 1 may be respectively slid along the two sliding tracks 20, the sliding tracks 20 can facilitate storing the hard disc bracket 1 within the computer case 2. The two openings 21 are located at first ends of the two sliding tracks 20, respectively.

FIG. 2 is a schematic top view illustrating the conventional hard disc bracket of FIG. 1. The hard disc bracket 1 comprises a frame 11, two locking elements 12, and two hooks 13. The frame 11 is used for accommodating a hard disc (not shown). The two locking elements 12 are located at a first side of the frame 11. In addition, the locking elements 12 are rotatable relative to the frame 11. The two hooks 13 correspond to the two locking elements 12, respectively. Moreover, the two hooks 13 are located at the first side of the frame 11, and disposed beside the locking elements 12. When the locking element 12 is rotated relative to the frame 11 to approach the corresponding hook 13, the locking element 12 and the hook 13 may be engaged with each other.

A process of fixing the hard disc on the computer case 2 will be illustrated as follows. Firstly, the hard disc is accommodated within the frame 11. Then, the two side plates 10 of the hard disc bracket 1 are respectively aligned with the two sliding tracks 20 of the computer case 2, and the hard disc bracket 1 is pushed to be slid into the computer case 2 along the two sliding tracks 20. Then, the two locking elements 12 are rotated relative to the frame 11 to approach the corresponding hooks 13, and the locking elements 12 and the corresponding hooks 13 are engaged with each other. As shown in FIG. 2, the lower locking element 12 is engaged with the corresponding hook 13. Moreover, during the two locking elements 12 are rotated relative to the frame 11, the first ends 121 of the locking elements 12 are inserted into corresponding openings 21 of the computer case 2. Consequently, the hard disc bracket 1 is in a locked state. Under this circumstance, the hard disc bracket 1 is fixed on the computer case 2.

On the other hand, a process of removing the hard disc from the computer case 2 will be illustrated as follows. Firstly, the two locking elements 12 are disengaged from the corresponding hooks 13, and the two locking elements 12 are rotated relative to the frame 11 to be distant from the frame 11. Meanwhile, the first ends 121 of the locking elements 12 are detached from corresponding openings 21 of the computer case 2. Consequently, the operating state of the hard disc bracket 1 is switched from the locked state to a released state. As shown in FIG. 2, the upper locking element 12 is disengaged from the corresponding hook 13. Afterwards, by pulling the two locking elements 12 in the direction distant from the computer case 2, the hard disc bracket 1 is removed from the computer case 2.

From the above discussions, the structure of the conventional hard disc bracket 1 may simplify the process of storing the hard disc and the process of removing the hard disc without the need of using a screwdriver or any other tool to disassemble the hard disc from the computer case. However, the conventional hard disc bracket 1 still has some drawbacks. For example, after the conventional hard disc bracket 1 has been used for a long time, the locking elements 12 and the hooks 13 are readily suffered from deformation or abrasion because of frequent collision. Under this circumstance, the engagement between the locking element 12 and the corresponding hook 13 is readily loosened. That is, the locked state of the hard disc bracket 1 is unstable and possibly switched to the released state. Therefore, there is a need of providing an improved hard disc bracket for stably fixing a hard disc.

### SUMMARY OF THE INVENTION

The present invention provides a hard disc bracket for stably fixing a hard disc.

In accordance with an aspect of the present invention, there is provided a hard disc bracket for fixing a hard disc within a computer case. The hard disc bracket includes a frame, at least one pushing lever, and a pulling lever. The frame is stored within the computer case for supporting the hard disc. The at least one pushing lever is located at a side of the frame and rotatable relative the frame for pushing the computer case, thereby facilitating detaching the frame from the computer case. The pulling lever is disposed on the frame and movable relative to the frame. When the frame is stored within the computer case and the pulling lever is pulled out, the at least one pushing lever is moved by the pulling lever and rotated relative to the frame in a first rotating direction, so that the computer case is pushed by the at least one pushing lever and the frame is detached from the computer case.

In an embodiment, the at least one pushing lever includes a middle segment and a fixing shaft. The fixing shaft is penetrated through the middle segment, so that the at least one pushing lever is fixed on the frame and the at least one pushing lever is rotatable relative to the frame.

In an embodiment, the at least one pushing lever further includes a first segment and a second segment. The first segment and the second segment are extended from the middle segment. In addition, the first segment and the second segment are integrally formed with the middle segment.

In an embodiment, the pulling lever includes a main body, an inner piece, and outer piece. The inner piece is located at a first side of the main body. When the pulling lever is moved toward a contact wall of the frame, the inner piece is contacted with the contact wall to push the frame into the computer case. When the pulling lever is pulled out, the first segment of the pushing lever is pulled by the inner piece, so that the pushing lever is rotated relative to the frame in the first rotating direction. The outer piece is located at a second side of the main body.

In an embodiment, when the pulling lever is pushed in a direction toward the contact wall, the first segment of the at least one pushing pieces is pushed by the outer piece, so that the at least one pushing lever is rotated relative to the frame in a second rotating direction and the frame is pushed by the inner piece to be introduced into the computer case.

In an embodiment, the main body is shorter than the inner piece, and the inner piece is shorter than the outer piece, so that the first segment of the at least one pushing lever is permitted to be inserted into a region between the inner piece and the outer piece and located near the main body. The inner piece and the outer piece are extended from the main body, and the inner piece and the outer piece are integrally formed with the main body.

In an embodiment, the frame further includes a position-limiting block. The position-limiting block is accommodated within the main body, so that the pulling lever is movable relative to the frame from a first position to a second position or from the second position to the first position.

In an embodiment, the main body further includes a groove, wherein the groove is formed in a bottom surface of the main body for accommodating the position-limiting block.

In an embodiment, the hard disc bracket further includes an elastic element, which is arranged between a contact wall of the frame and the pulling lever. A first terminal of the elastic element is in contact with the contact wall, and a second terminal of the elastic element is in contact with the pulling lever. The elastic element provides an elastic force to the pulling lever, thereby preventing detachment of the pulling lever from the frame.

In an embodiment, the pulling lever further includes a receptacle, which is disposed within a main body of the pulling lever for accommodating the second terminal of the elastic element. The receptacle has a receptacle opening, which is located at a first side of the pulling lever, wherein the first terminal of the elastic element is in contact with the contact wall through the receptacle opening.

In an embodiment, the computer case further includes plural resilience sheets, which are located at bilateral sides of the computer case. When the frame is stored within the computer case, the plural resilience sheets are sustained against the frame, thereby preventing detachment of the frame from the computer case.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a schematic perspective view illustrating the relationship between a hard disc bracket and a computer case according to the prior art;

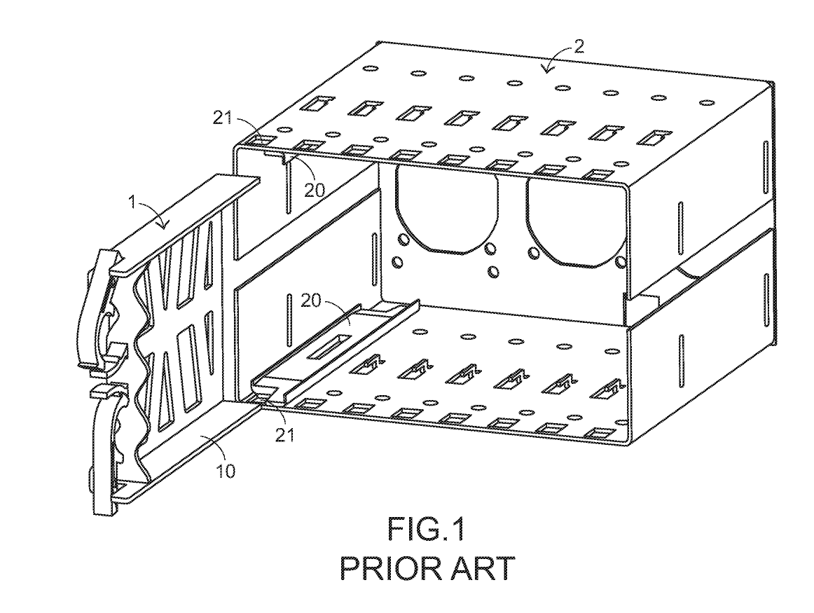

FIG. 2 is a schematic top view illustrating the conventional hard disc bracket of FIG. 1;

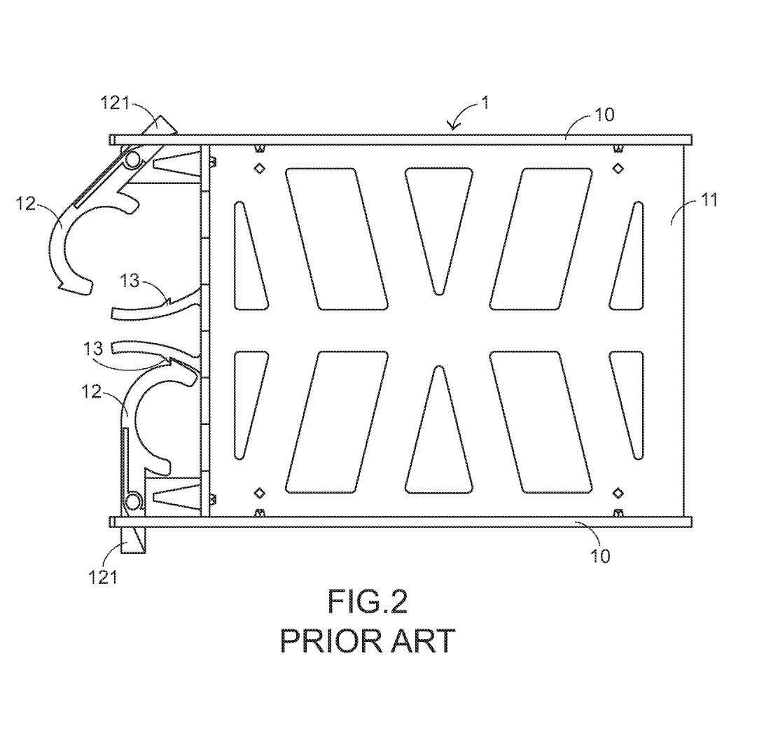

FIG. 3 is a schematic perspective view illustrating the relationship between a hard disc bracket and a computer case according to an embodiment of the present invention;

FIG. 4 is a schematic top view illustrating the hard disc bracket stored within the computer case according to an embodiment of the present invention;

FIG. 5 is a schematic exploded view illustrating the hard disc bracket according to the embodiment of the present invention;

FIG. 6 is a schematic exploded view illustrating the pulling lever and the frame of the hard disc bracket of FIG. 5 and taken along another viewpoint; and

FIG. 7 is a schematic top view illustrating the hard disc bracket removed from the computer case according to an embodiment of the present invention.

### DETAILED DESCRIPTION OF THE PREFERRED EMBODIMENT

For obviating the drawbacks encountered from the prior art, the present invention provides a hard disc bracket.

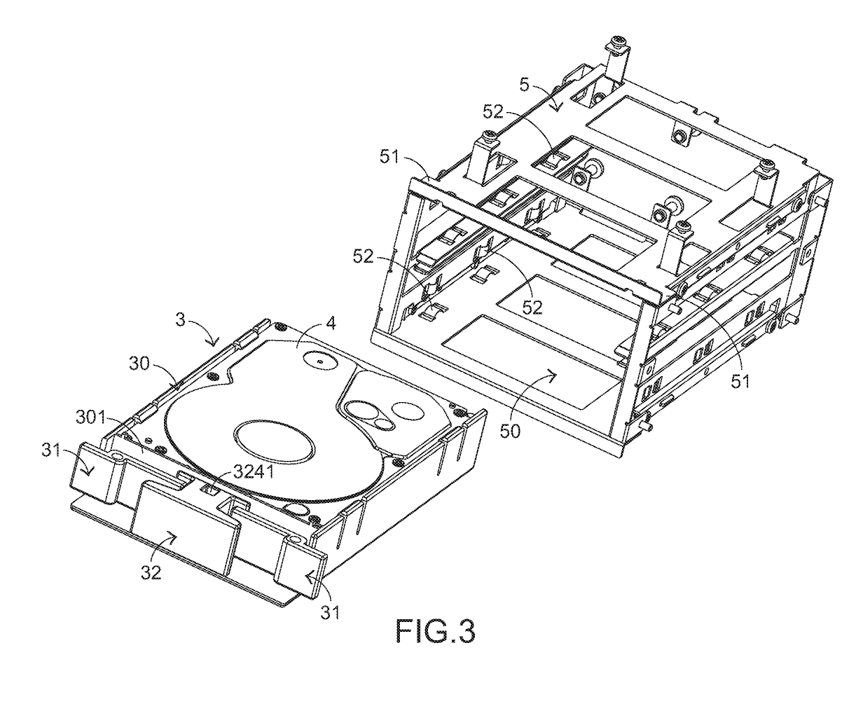

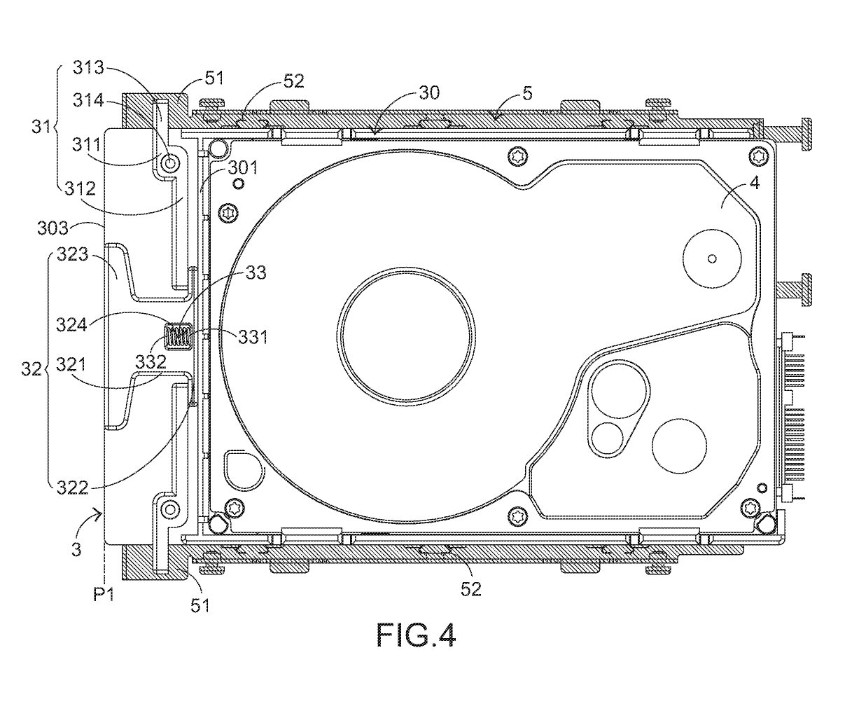

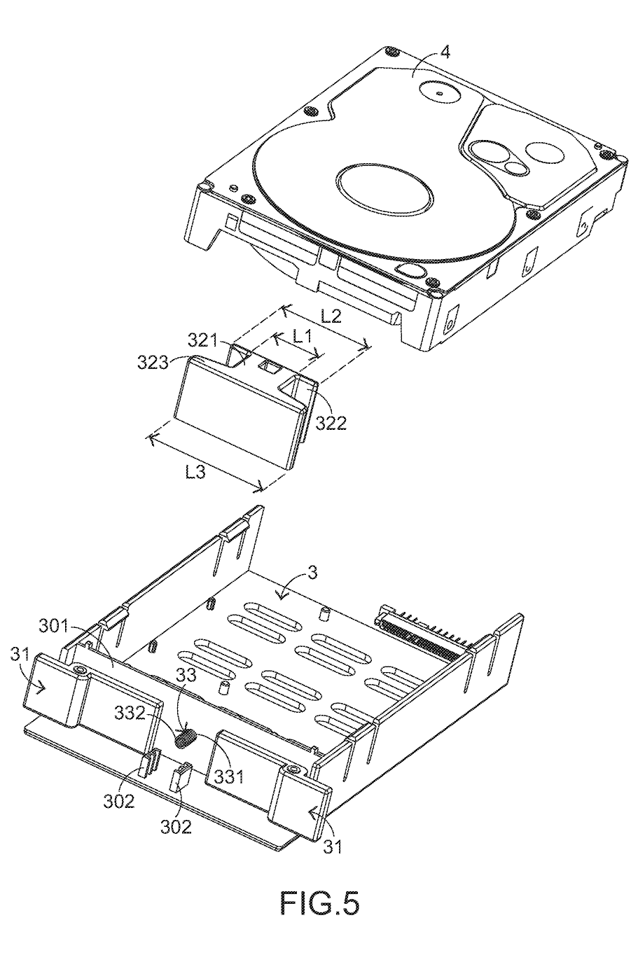

Please refer to FIGS. 3 and 4. FIG. 3 is a schematic perspective view illustrating the relationship between a hard disc bracket and a computer case according to an embodiment of the present invention. FIG. 4 is a schematic top view illustrating the hard disc bracket stored within the computer case according to an embodiment of the present invention. In FIG. 3, a hard disc bracket 3, a hard disc 4 and a computer case 5 are shown. The hard disc bracket 3 comprises a frame 30, two pushing levers 31, a pulling lever 32, and an elastic element 33. The frame 30 may be stored within the computer case 5. In addition, the frame 30 is used for supporting and accommodating the hard disc 4. The frame 30 comprises a contact wall 301 and a position-limiting block 302 (see FIG. 5). The pushing levers 31 are located at a first side of the frame 30, and rotatable relative to the frame 30. The pushing levers 31 are used for pushing the computer case 5 in order to facilitate detaching the frame 30 from the computer case 5. The pulling lever 32 is disposed on the frame 30, and movable relative to the frame 30. When the pulling lever 32 is pulled by the user, the two pushing levers 31 are pulled by the pulling lever 32, so that the two pushing levers 31 are rotated relative to the frame 30. The elastic element 33 is arranged between the contact wall 301 of the frame 30 and the pulling lever 32. A first terminal 331 of the elastic element 33 is in contact with the contact wall 301. A second terminal 332 of the elastic element 33 is in contact with the pulling lever 32. The elastic element 33 is used for providing an elastic force to the pulling lever 32. In this embodiment, the elastic element 33 is a spring.

Please refer to FIG. 3 again. The computer case 5 comprises an entrance/exit 50, two concave structures 51, and plural resilience sheets 52. The entrance/exit 50 is located at a front end of the computer case 5. Through the entrance/exit 50, the hard disc bracket 3 may be introduced into the computer case 5 or removed from the computer case 5. The two concave structures 51 are located at bilateral sides of the computer case 5 and disposed beside the entrance/exit 50. The plural resilience sheets 52 are disposed within the computer case 5, and located at the bilateral sides of the computer case 5. After the frame 30 is stored within the computer case 5, the plural resilience sheets 52 are sustained against the frame 30 in order to avoid detachment of the frame 30 from the computer case 5. As shown in FIG. 4, each of the pushing levers 31 comprises a middle segment 311, a first segment 312, a second segment 313, and a fixing shaft 314. The first segment 312 and the second segment 313 are extended from the middle segment 311. The first segment 312 of the pushing lever 31 is parallel with the second segment 313 of the pushing lever 31. The fixing shaft 314 is penetrated through the middle segment 311, so that the pushing lever 31 is fixed on the first side of the frame 30. In addition, the pushing lever 31 is rotatable relative to the frame 30 by using the fixing shaft 314 as a fulcrum. In this embodiment, the middle segment 311, the first segment 312 and the second segment 313 are made of plastic material, and the fixing shaft 314 is made of metallic material. More preferably, the middle segment 311, the first segment 312 and the second segment 313 are integrally formed with each other. Alternatively, in some embodiments, the middle segment 311, the first segment 312, the second segment 313 and the fixing shaft 314 are all made of plastic material, and the middle segment 311, the first segment 312, the second segment 313 and the fixing shaft 314 are integrally formed with each other.

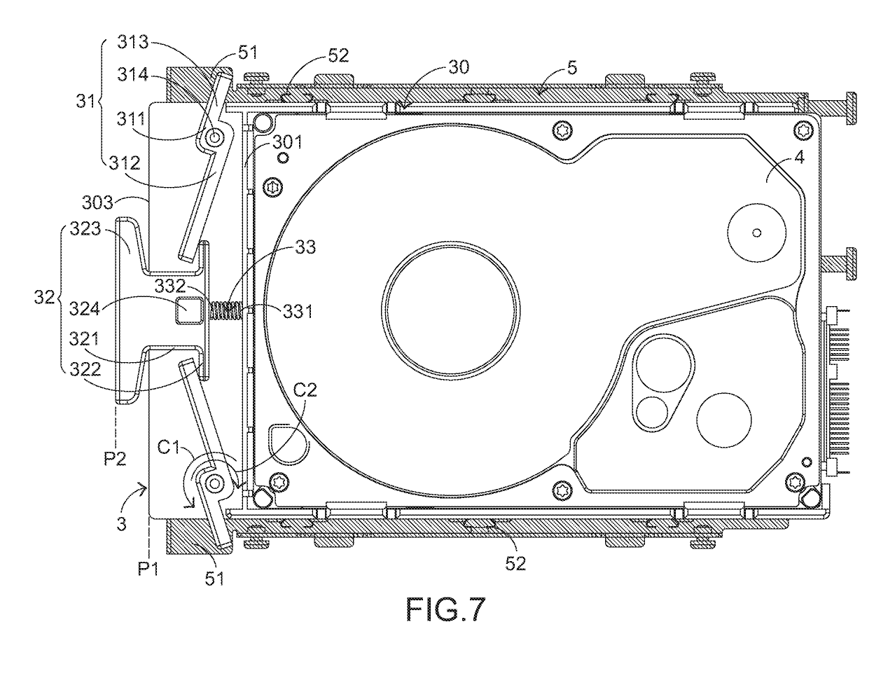

Please refer to FIG. 4 again. The pulling lever 32 comprises a main body 321, an inner piece 322, an outer piece 323, and a receptacle 324. The inner piece 322 is located at a first side of the main body 321, and extended from the main body 321. When the pulling lever 32 is pulled out, the first segment 312 of the pushing lever 31 is pulled by the inner piece 322, so that the pushing lever 31 is rotated relative to the frame 30 in a first rotating direction C1 (see FIG. 7). The outer piece 323 is located at a second side of the main body 321, and extended from the main body 321. When the pulling lever 32 is pushed in the direction toward the contact wall 301 of the frame 30, the first segment 312 of the pushing lever 31 is pushed by the outer piece 323 of the pulling lever 32, so that the pushing lever 31 is rotated relative to the frame 30 in a second rotating direction C2 (see FIG. 7). At the same time, the inner piece 322 is contacted with the contact wall 301 of the frame 30 to push the frame 30 into the computer case 5 (see FIG. 4).

In this embodiment, the inner piece 322 and the outer piece 323 are integrally formed with the main body 321. The receptacle 324 is disposed within the main body 321 for accommodating the second terminal 332 of the elastic element 33. Moreover, the receptacle 324 has a receptacle opening 3241 (see FIG. 3). The receptacle opening 3241 is located at the first side of the pulling lever 32. The first terminal 331 of the elastic element 33 is in contact with the contact wall 301 through the receptacle opening 3241.

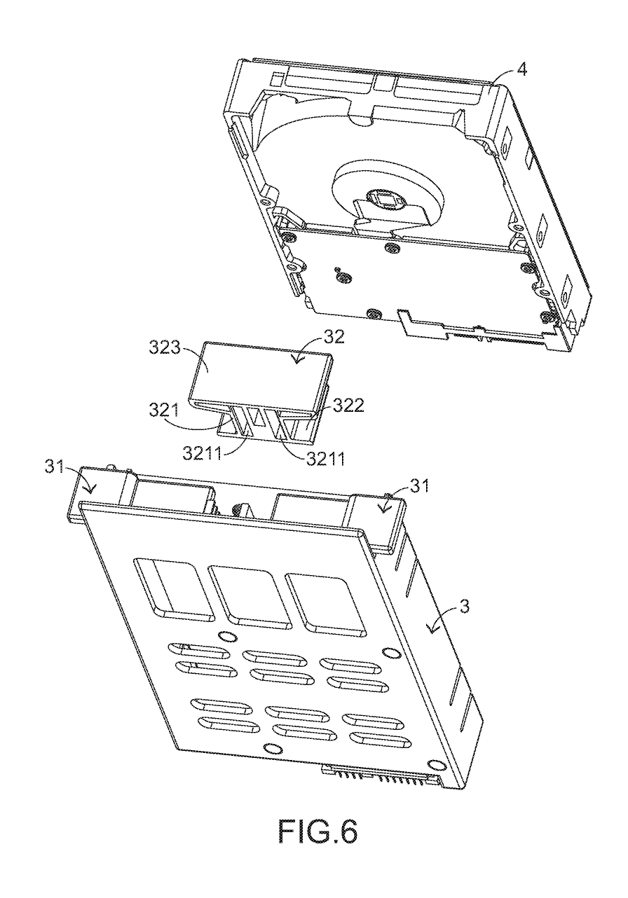

FIG. 5 is a schematic exploded view illustrating the hard disc bracket according to the embodiment of the present invention. FIG. 6 is a schematic exploded view illustrating the pulling lever and the frame of the hard disc bracket of FIG. 5 and taken along another viewpoint. As shown in FIG. 5, the length L1 of the main body 321 of the pulling lever 32 is smaller than the length L2 of the inner piece 322 of the pulling lever 32. The length L2 of the inner piece 322 is smaller than the length L3 of the outer piece 323 of the pulling lever 32. Consequently, the first segment 312 of the pushing lever 31 may be inserted into the region between the inner piece 322 and the outer piece 323, and located near the main body 321. In addition, the main body 321 of the pulling lever 32 comprises a groove 3211. The groove 321 is formed in a bottom surface of the main body 321 for accommodating the position-limiting block 302 of the frame 30. That is, the position-limiting block 302 is inserted into the groove 3211 of the main body 321 of the pulling lever 32 for limiting the specified movable range of the pulling lever 32 relative to the frame 30. The specified movable range of the pulling lever 32 is dependent on the length of the groove 3211. The definition of the specified movable range of the pulling lever 32 will be illustrated in more details later.

FIG. 7 is a schematic top view illustrating the hard disc bracket removed from the computer case according to an embodiment of the present invention. Hereinafter, a process of removing the hard disc bracket 3 from the computer case 5 will be illustrated with reference to FIGS. 4 and 7. As shown in FIG. 4, the hard disc bracket 3 is stored within the computer case 5. The relationships between the components of the hard disc bracket 3 will be illustrated as follows. The inner piece 322 of the pulling lever 32 is in contact with the contact wall 301 of the frame 30, and thus the pulling lever 32 is in a first position P1. Meanwhile, the elastic element 33 is pushed and compressed by the contact wall 301, and stored within the receptacle 324. Moreover, the first segments 312 of the two pushing levers 31 are in contact with the inner piece 322 of the pulling lever 32, the first segments 312 of the two pushing levers 31 are parallel with the contact wall 301 of the frame 30, and the second segments 313 of the two pushing levers 31 are inserted into the concave structures 51 of the computer case 5.

When the user wants to remove the hard disc bracket 3 from the computer case 5, the outer piece 323 of the pulling lever 32 is externally pulled out by the user in the direction distant from the contact wall 301 of the frame 30. Consequently, the pulling lever 32 is moved from the first position P1 to a second position P2 with respect to the frame 30 (see FIG. 7). In other words, the specified movable range is the range between the first position P1 and the second position P2. During the pulling lever 32 is pulled out, the first segments 312 of the two pushing levers 31 are pulled by the inner piece 322 of the pulling lever 32. Consequently, the two pushing levers 31 are rotated relative to the frame 30 in the first rotating direction C1 by using the fixing shafts 314 as the fulcrums. As the two pushing levers 31 are rotated in the first rotating direction C1, the computer case 5 is pushed by the second segments 313 of the two pushing levers 31. Consequently, the frame 30 is detached from the computer case 5, and the hard disc bracket 3 is removed from the computer case 5.

However, since there is no fixing mechanism between the position-limiting block 302 of the frame 30 and the groove 3211 of the main body 321, if the pulling lever 32 is not in contact with the pushing levers 31, the pulling lever 32 is readily detached from the frame 30. For solving this problem, when the pulling lever 32 is pulled out and the pulling lever 32 is moved relative to the frame 30 to the second position P2, the elastic element 33 provides an elastic force to the pulling lever 32 to support the pulling lever 32. Consequently, the possibility of detaching the pulling lever 32 from the frame 30 will be minimized. Alternatively, in some embodiments, a fixing mechanism is arranged between the position-limiting block and the groove to replace the elastic element.

On the other hand, when the user wants to store the hard disc bracket 3 within the computer case 5, the frame 30 is firstly aligned with the entrance/exit 50 of the computer case 5, and then the pulling lever 32 is pushed in the direction toward the contact wall 301. Consequently, the pulling lever 32 is moved relative to the frame 30 from the second position P2 to the first position P1. At the same time, the elastic element 33 is compressed and stored within the receptacle 324, so that the pulling lever 32 is in contact with the contact wall 301. Moreover, during the pulling lever 32 is moved from the second position P2 to the first position P1, the first segments 312 of the two pushing pieces 323 are pushed by the outer piece 323. Consequently, the two pushing levers 31 are rotated relative to the frame 30 in a second rotating direction C2 by using the fixing shafts 314 as the fulcrums. In addition, the contact wall 301 of the frame 30 is pushed by the inner piece 322, so that the frame 30 is introduced into and stored within the computer case 5. Meanwhile, the hard disc bracket 3 is stored within the computer case 5.

Please refer to FIG. 4 again. After the hard disc bracket 3 is stored within the computer case 5, the pulling lever 32 is in the first position P1, and the pulling lever 32 is aligned with a front edge 303 of the frame 30. Consequently, the user can realize whether the hard disc bracket 3 is stored within the computer case 5 by judging whether the pulling lever 32 is aligned with the front edge 303 of the frame 30 with naked eyes.

From the above description, the present invention provides a hard disc bracket. When the pulling lever of the hard disc bracket is pulled out, the pushing levers are pulled by the pulling lever, so that the computer case is pushed by the pushing levers and the frame is detached from the computer case. Since the associated components of the hard disc bracket of the present invention are not engaged with each other, even if the hard disc bracket has been used for a long time, the possibility of suffering from abrasion will be minimized. Moreover, the user can realize whether the hard disc bracket is properly stored within the computer case by judging whether the pulling lever is aligned with the front edge of the frame with naked eyes. Consequently, the hard disc bracket of the present invention can be stably stored within the computer case.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A hard disc bracket for fixing a hard disc within a computer case, said hard disc bracket comprising:
a frame stored within said computer case for supporting said hard disc;
at least one pushing lever located at a side of said frame and rotatable relative said frame for pushing said computer case, thereby facilitating detaching said frame from said computer case; and
a pulling lever disposed on said frame and movable relative to said frame, wherein when said frame is stored within said computer case and said pulling lever is pulled out, said at least one pushing lever is moved by said pulling lever and rotated relative to said frame in a first rotating direction, so that said computer case is pushed by said at least one pushing lever and said frame is detached from said computer case.

2. The hard disc bracket according to claim 1, wherein said at least one pushing lever comprises:
a middle segment; and
a fixing shaft penetrated through said middle segment, so that said at least one pushing lever is fixed on said frame and said at least one pushing lever is rotatable relative to said frame.

3. The hard disc bracket according to claim 2, wherein said at least one pushing lever further comprises a first segment and a second segment, wherein said first segment and said second segment are extended from said middle segment, and said first segment and said second segment are integrally formed with said middle segment.

4. The hard disc bracket according to claim 1, wherein said pulling lever comprises:
a main body;
an inner piece located at a first side of said main body, wherein when said pulling lever is moved toward a contact wall of said frame, said inner piece is contacted with said contact wall to push said frame into said computer case, wherein when said pulling lever is pulled out, said first segment of said pushing lever is pulled by said inner piece, so that said pushing lever is rotated relative to said frame in said first rotating direction; and
an outer piece located at a second side of said main body.

5. The hard disc bracket according to claim 4, wherein when said pulling lever is pushed in a direction toward said contact wall, said first segment of said at least one pushing pieces is pushed by said outer piece, so that said at least one pushing lever is rotated relative to said frame in a second rotating direction and said frame is pushed by said inner piece to be introduced into said computer case.

6. The hard disc bracket according to claim 4, wherein said main body is shorter than said inner piece, and said inner piece is shorter than said outer piece, so that said first segment of said at least one pushing lever is permitted to be inserted into a region between said inner piece and said outer piece and located near said main body, wherein said inner piece and said outer piece are extended from said main body, and said inner piece and said outer piece are integrally formed with said main body.

7. The hard disc bracket according to claim 4, wherein said frame further comprises a position-limiting block, wherein said position-limiting block is accommodated within said main body, so that said pulling lever is movable relative to said frame from a first position to a second position or from said second position to said first position.

8. The hard disc bracket according to claim 7, wherein said main body further comprises a groove, wherein said groove is formed in a bottom surface of said main body for accommodating said position-limiting block.

9. The hard disc bracket according to claim 1, further comprising an elastic element, which is arranged between a contact wall of said frame and said pulling lever, wherein a first terminal of said elastic element is in contact with said contact wall, and a second terminal of said elastic element is in contact with said pulling lever, wherein said elastic element provides an elastic force to said pulling lever, thereby preventing detachment of said pulling lever from said frame.

10. The hard disc bracket according to claim 9, wherein said pulling lever further comprises a receptacle, which is disposed within a main body of said pulling lever for accommodating said second terminal of said elastic element, wherein said receptacle has a receptacle opening, which is located at a first side of said pulling lever, wherein said first terminal of said elastic element is in contact with said contact wall through said receptacle opening.

11. The hard disc bracket according to claim 1, wherein said computer case further comprises plural resilience sheets, which are located at bilateral sides of said computer case, wherein when said frame is stored within said computer case, said plural resilience sheets are sustained against said frame, thereby preventing detachment of said frame from said computer case.
